(19) United States
(12) Patent Application Publication
(10) Pub. No.: US 2007/0096132 A1
(43) Pub. Date: May 3, 2007

(54) Coaxial LED lighting board

(76) Inventor: Jiahn-Chang Wu, Chuntung (TW)

Correspondence Address: LOWE HAUPTMAN BERNER, LLP, 1700 DIAGONAL ROAD, SUITE 300, ALEXANDRIA, VA, 22314, US

(21) Appl. No.: 11/262,820

(22) Filed: Nov. 1, 2005

(51) Int. Cl. H01L 33/00; H01L 29/22

(52) U.S. Cl. 257/99

(57) ABSTRACT

A lighting board is fabricated with. the use of coaxial light device inserted in a socket plate, the convenience of assembly and disassembly of the coaxial light device with its coaxial lead makes the product easily to be maintained for changing different color of the coaxial light device, changing different lighting pattern, or remove/replace a failure coaxial light device.

### BACKGROUND OF THE INVENTION

(1) Field of the Invention

This invention relates to a lighting board of diode with a coaxial lead to be the light source, which can be used as an indicator, decoration board, amusement combination lighting board, car headlight, or image display.

(2) Brief Description of Related Art

FIG. 1. shows a related prior art. It shows a traditional structure of a LED display. Metal wires 10a and 10b is formed on the top surface of a circuit board substrate 10. A LED chip 11 has two bottom electrodes 11 a and 11 b, flip-chip bonded to the substrate 10 with its two bottom electrodes 11 a, 11 b respectively coupled to the metal circuits 10a and 10b of the substrate 10. Because of the adhesion bonded structure of the chip 11 to the substrate 20, the prior art has several drawbacks comprising:

(a) Lack of flexibility to change different color LED; (b) Lack of flexibility to change different lighting patterns of the display; (c) Inconvenient maintenance for changing a failure LED.

### SUMMARY OF THIS INVENTION

This invention adopts a coaxial diode as its lighting source, with the coaxial single lead of the coaxial diode, the coaxial lighting device is easily to be plug and unplug. A socket plate is designed for accommodation of the coaxial lighting device and therefore forming a simple structure and easily maintained display board. A first object of this invention is to provide a lighting board that is easily to plug and unplug the lighting element. A second object of this invention is to provide a lighting board that is easily to change the displayed pattern. A third object of this invention is to provide a lighting board that is easily to replace a malfunction lighting element. A fourth object of this invention is to provide a lighting board that is assembled without using any solder, glue, nut, bolt or screw in the combination of the elements.

### BRIEF DESCRIPTION OF THE DRAWINGS

FIG. 1. is a section view of a prior art LED display.

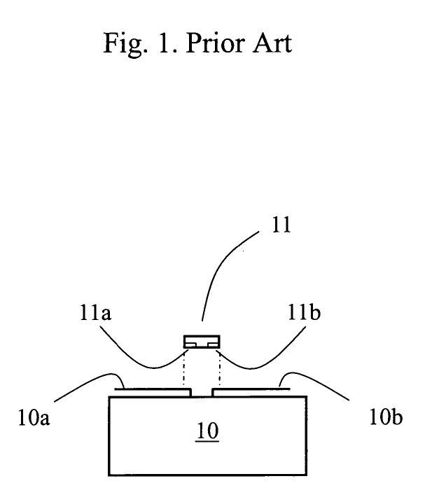

FIG. 2. is a coaxial LED to be a light, source used in this invention.

FIG. 3. is a first embodiment of this invention.

FIG. 4. is a second embodiment of the socket plate of this invention.

FIG. 5. is a third embodiment of the socket plate of this invention.

FIG. 6. is a fourth embodiment of the socket plate of this invention.

FIG. 7. is a fifth embodiment of the socket plate of this invention.

FIG. 8. is a sixth embodiment of the socket plate of this invention.

FIG. 9. is a seventh embodiment of the socket plate of this invention.

FIG. 10. is an eighth embodiment of the socket plate of this invention.

FIG. 11. is a ninth embodiment of the socket plate of this invention.

FIG. 12. is a tenth embodiment of the socket plate of this invention.

FIG. 13. is an eleventh embodiment of the socket plate of this invention.

FIG. 14. is a twelfth embodiment of the socket plate of this invention.

FIG. 15. is a second embodiment of this invention.

FIG. 16. is a third embodiment of this invention.

FIG. 17. is a fourth embodiment of this invention.

### DETAILED DESCRIPTION OF T INVENTION

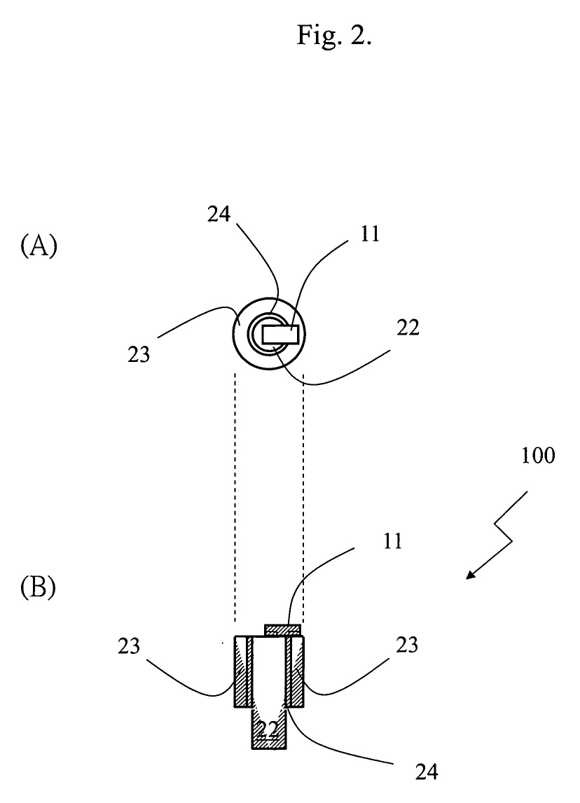

FIG. 2. is a coaxial LED to be a light s used in this invention.

FIG. 2A shows the top view of a coaxial LED and FIG. 2B shows the section view of a coaxial LED.

Referring to FIG. 2A, a light emitting diode chip 11 is mounted on a coaxial lead that comprises an outer metal lead 23 and an inner metal lead 22, an insulation layer 24 is inserted in between to isolate the outer metal lead 23 and the inner metal lead 22. The bottom electrodes 11 a, 1 lb of the chip 11 are respectively electrically coupling to the outer metal lead 23 and inner metal lead 22. FIG. 2B shows a coaxial LED 100 has an outer metal lead 23 and an inner metal lead 22, the inner metal lead 22 has its bottom protruded and exposed out of the outer metal lead 23, an isolation layer 24 is used to isolate the outer metal lead 23 and the inner metal lead 22. Chip 11 is on the top of the coaxial metal leads, the bottom electrodes 11 a, 11 b are respectively coupling to the outer metal lead 23 and inner metal lead 22.

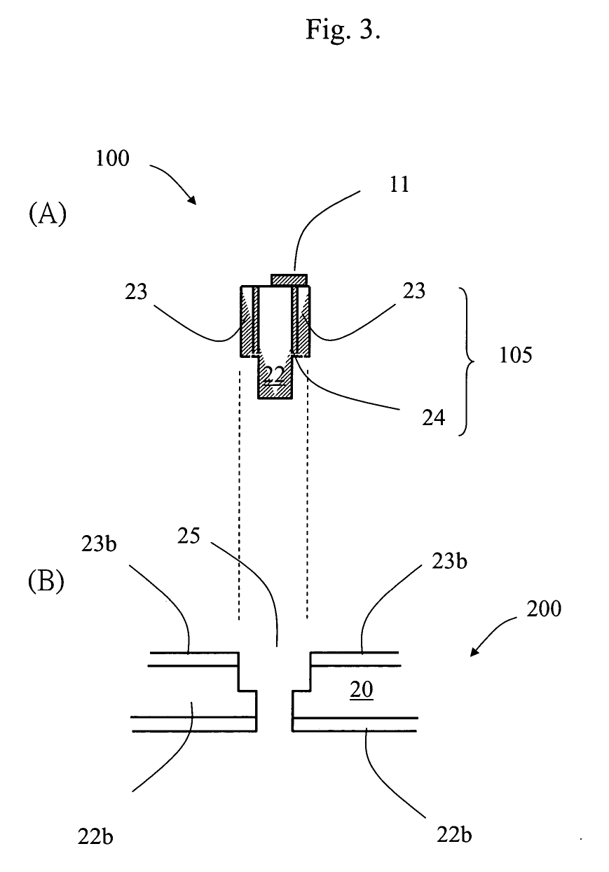

FIG. 3. is a first embodiment of this invention.

FIG. 3 shows a socket plate 200 made of metal/substrate/metal sandwich structure. A step opening 25 is formed in the substrate 20 for the coaxial LED 100 to plug in A piece of metal layer 23b is stacked on the top surface of the substrate 20, and a bottom metal layer 22b is stacked on the bottom surface of the substrate 20. W1 the LED is inserted, the top metal layer 23b of the socket plate 200 is coupling to the outer metal lead 23 of the LED 100 by its side, the bottom metal layer 22b is coupling to the inner metal lead 22 of the LED 100 by its side.

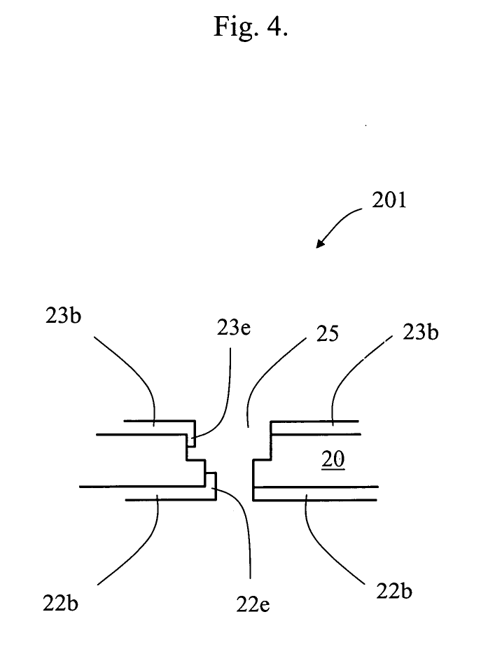

FIG. 4. is a second embodiment of the socket plate of this invention.

FIG. 4 shows a different design of the socket plate 201 from that in FIG. 3, FIG. 4 shows that both the top metal 23b and bottom metal 22b extends into the opening 25 for a better electrically contact inside the opening 25. Top metal 23b bents its end 23e into the opening 25 to provide more metal contact area with the outer metal lead 23, in a similar way, the bottom metal 22b bents its end 22e into the opening 25 to provide more metal contact area with the inner metal lead 22. The bending metal 233, 22e supplies more contact area than that as shown in FIG. 3 with the electrodes 23, 22 of LED 100.

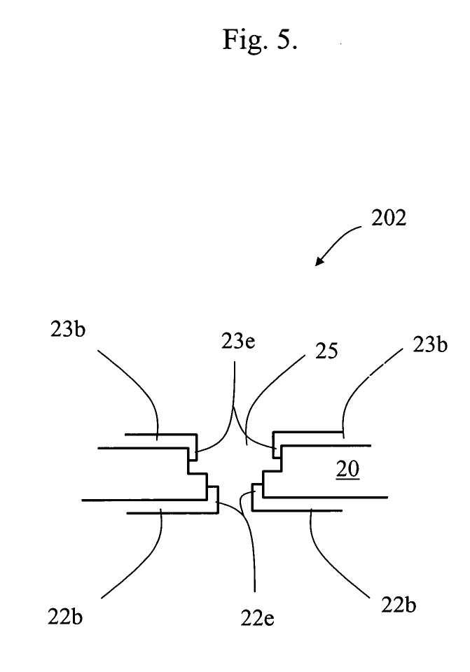

FIG. 5. is a third embodiment of the socket plate of this invention.

FIG. 5 shows a different design for socket plate 202, it is similar to that of FIG. 4 except for the amount of the extension metal 23e, 22e. FIG. 5 shows more extension metal 23e, 22e bends into the opening 25 for a better electrical contact to the electrodes 23, 22 of the coaxial LED 100 when the coaxial LED 100 is inserted.

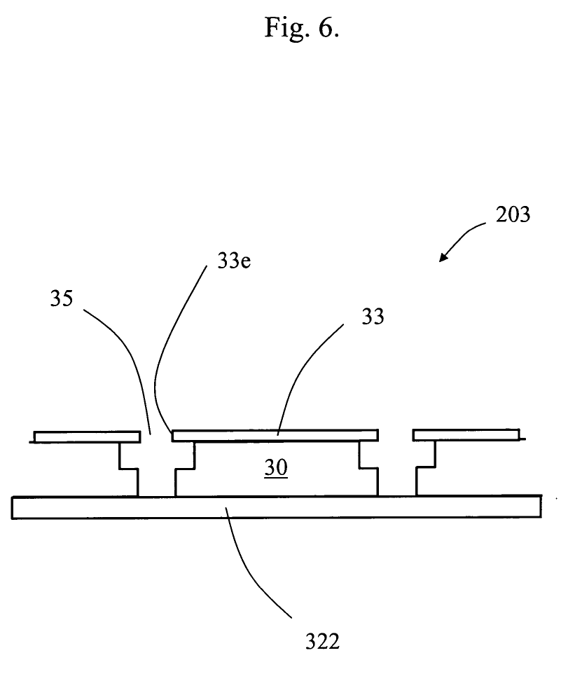

FIG. 6. is a fourth embodiment of the socket plate of this invention.

FIG. 6 shows a further different design for the socket plate 203, a top metal 33 with extension 33e protruded into the opening 35, and a flat bottom metal 322 sandwich a substrate 30 in between the two metals 3, 322. The extension 33e is waiting to be bent when inserting a coaxial LED 100.

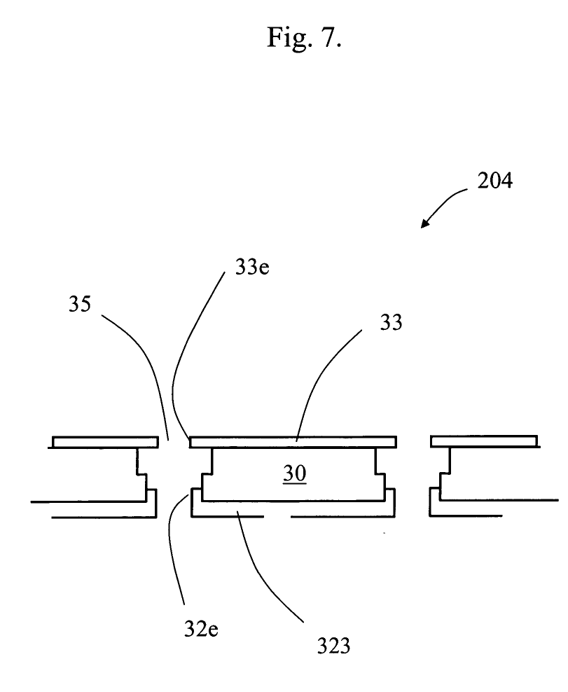

FIG. 7. is a fifth embodiment of the. socket plate of this invention.

FIG. 7 shows modification to the bottom metal 322 of FIG. 6. The socket plate 204 in FIG. 7 discloses a bottom metal plate 323 with their extension 32e bent inside the opening 35 for better contact with the inner metal lead 22 of the coaxial LED 100 to be inserted.

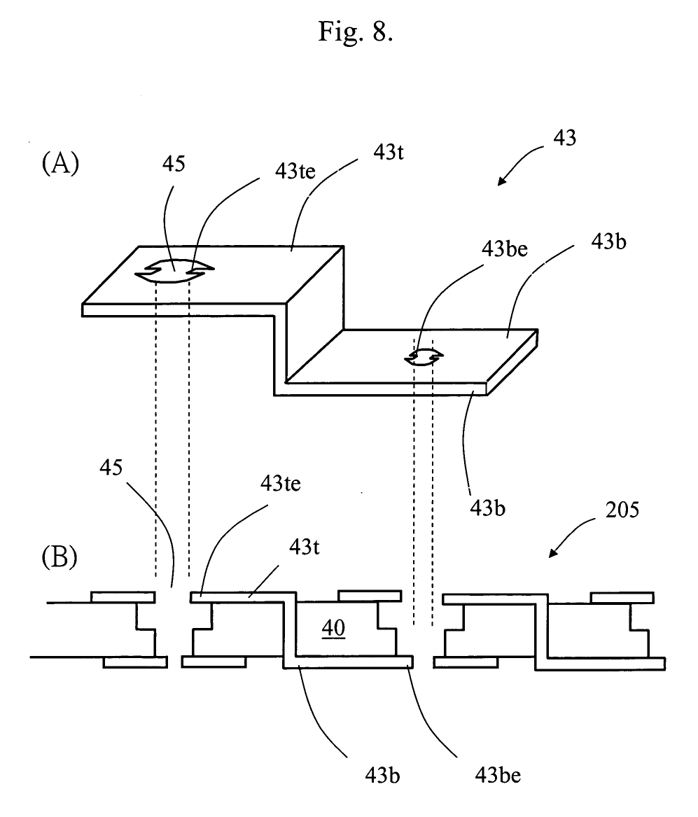

FIG. 8. is a sixth embodiment of the socket plate of this invention.

The previous socket plates provide electrically parallel connection among a plurality of coaxial LEDs 100 to be inserted. However FIG. 8 shows a socket plate 205 to provide electrically serial connection among a plurality of coaxial LEDs 100. A Z-shaped metal is inside of the substrate 40 with a top metal 43t over the substrate 40 and a bottom metal 43b under the substrate 40. FIG. 8A shows the three-dimension view to the z shaped metal 43 that comprises a top metal 43t and a bottom metal 43b and with openings 45 each on the top metal 43t and the bottom metal 43b. The top metal 43t and the bottom metal 43b is connected by a connection metal. The top metal 43t has metal extensions 43te protruded into the opening 45 for bending into the opening 45 when a coaxial LED 100 is inserted, and the bottom metal 43b has metal extensions 43e protruded into the opening 45 providing flexible contact to the inner lead 22 of the coaxial LED 100 when a coaxial LED 100 is inserted.

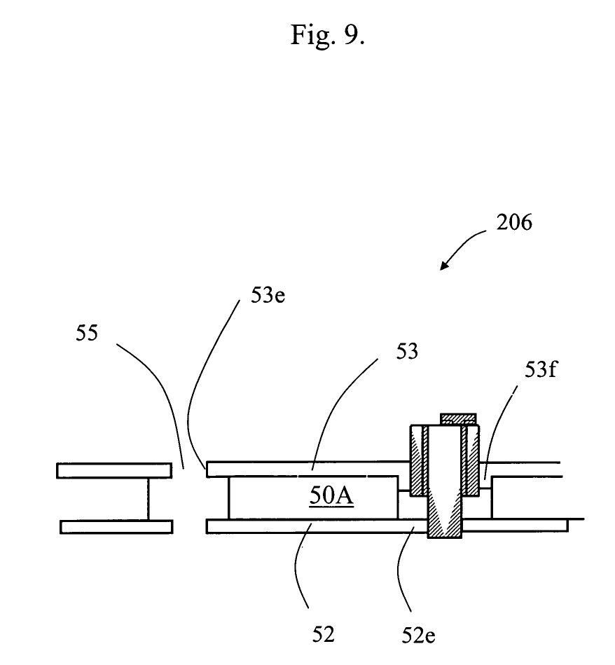

FIG. 9. is a seventh embodiment of the socket plate of this invention.

FIG. 9 shows still another design to the socket plate 206, the opening 55 in the substrate 50A is made rectangle instead of a step in section view. The top metal 53 has extension 53e to be bent into the opening 55 becoming a metal contact 53f when a coaxial LED 100 inserts. The bottom metal 52 has extension 52e to electrically couple with the inner lead 22 of the coaxial LED 100 when a coaxial LED 100 inserts.

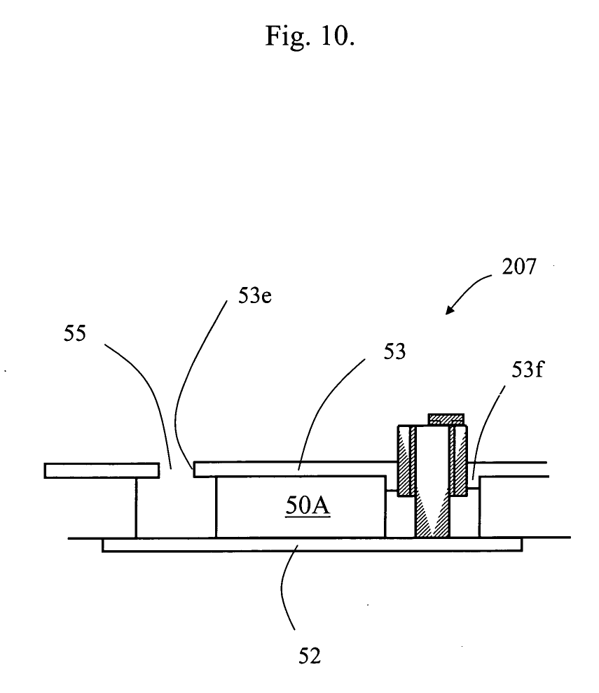

FIG. 10. is an eighth embodiment of the socket plate of this invention.

FIG. 10 show still another design to the socket plate 207, the bottom metal 52 is a flat metal plate for a flexible contact with the inner lead 22 of the coaxial LED 100 when a coaxial LED 100 inserts.

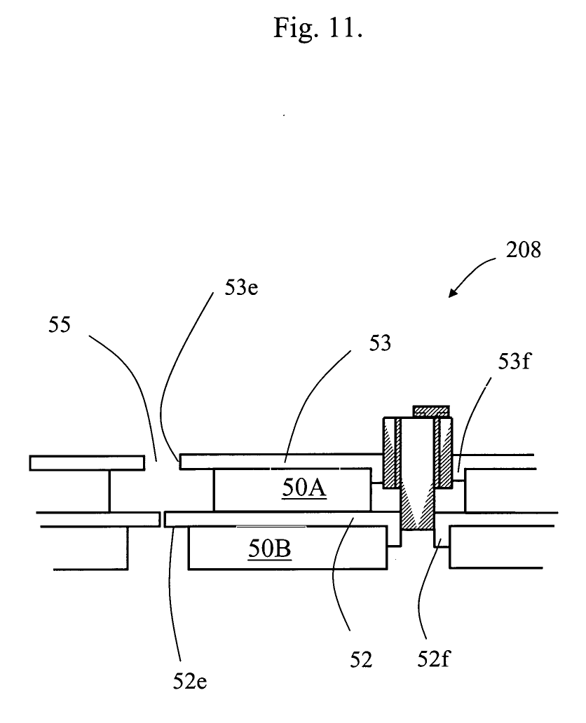

FIG. 11. is a ninth embodiment of the socket plate of this invention.

FIG. 11 shows double substrates 50A and SOB, a top metal 53 with extension 53e stacks over the first substrate 50A and a bottom metal 52 with extension 52e stacks over the second substrate SOB, top metal 53, first substrate 50A, bottom metal 52, and second substrate 50B are stacked. The extensions 53e, 52e are bent inside the opening 55 when a coaxial LED 100 inserts.

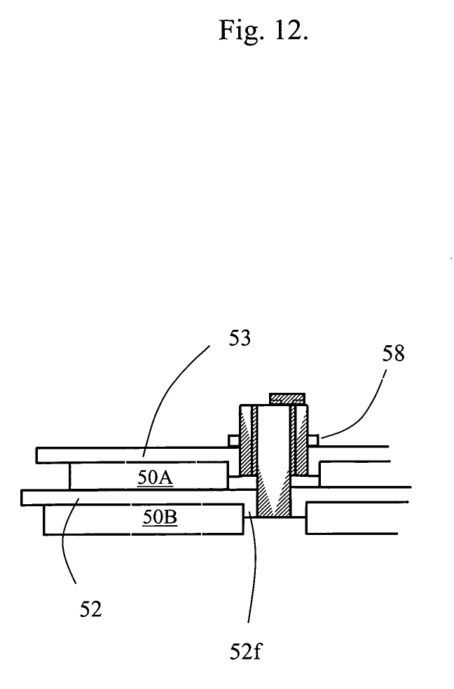

FIG. 12. is a tenth embodiment of the socket plate of this invention.

FIG. 12 shows a flange 58 is made around the coaxial metal leads as a stop for the coaxial LED 100 to insert properly and remain partially of the metal leads above the surface of the top metal 53 for easily plug and unplug of the coaxial LEDs 100.

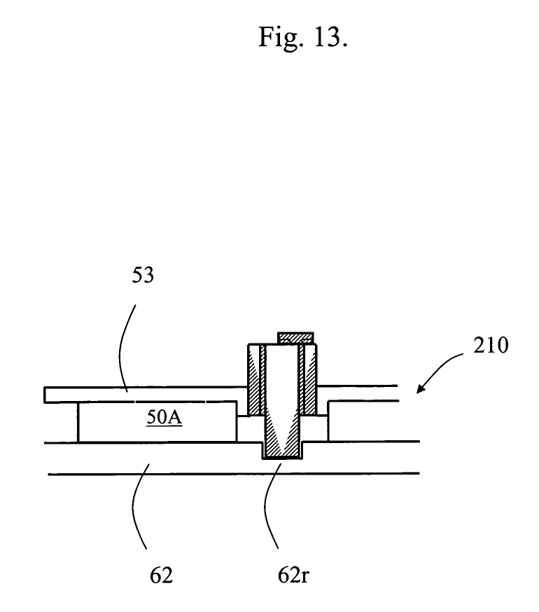

FIG. 13. is an eleventh embodiment of the socket plate of this invention.

FIG. 13 shows the bottom metal 62 has a recess 62r for accommodation of the inner metal lead 22 of the inserted coaxial LED 100.

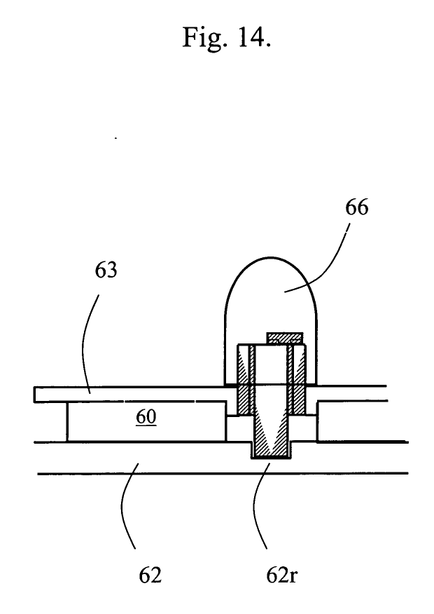

FIG. 14. is a twelfth embodiment of the socket plate of this invention.

FIG. 14 shows that protection glue 66 can be used to protect the chip 11 and top portion of the metal lead of the coaxial LED 100.

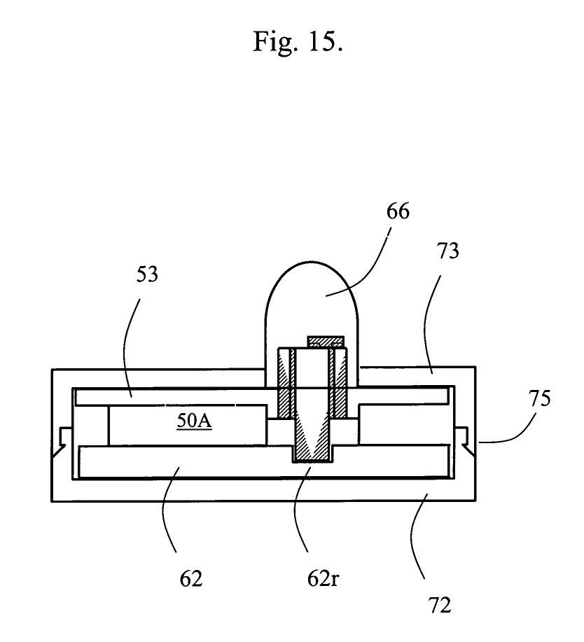

FIG. 15. is a second embodiment of this invention.

FIG. 15 shows a clip case with a top cover 73 and a bottom cover 72 can be used to pinch the elements of the coaxial LED and the top metal 53, substrate 50A, and the bottom metal 62 with a clip structure 75 and without using any glue, solder, nut, bolt, screw . . . ect. in between the elements of the socket plate.

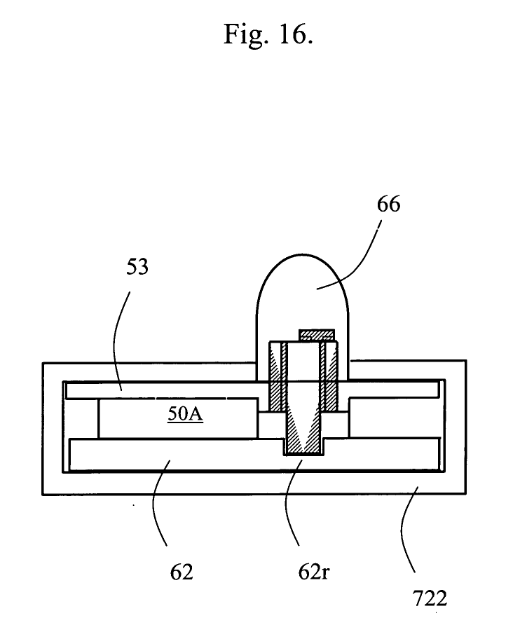

FIG. 16. is a third embodiment of this invention.

FIG. 16 shows a permanent sealing case 722 is used for waterproof.

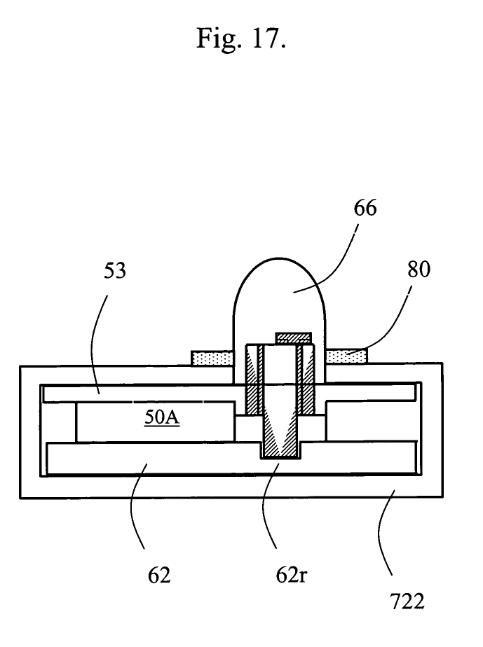

FIG. 17. is a fourth embodiment of this invention.

FIG. 17 shows additional waterproof material can be applied around the junction between the coaxial LED 100 and the top surface of the case 722.

A smooth coaxial lead is illustrated in this invention, however, a spiral (not shown in the figure) can be formed around the outer metal 23 of the metal lead 105, so the lighting device can be screwing into the socket plate 200. A coaxial LED is illustrated in this invention disclosure, however different lighting device with a coaxial lead can be used according to this invention. While the preferred embodiments have been described, it will be apparent to those skilled in the art that various modification may be made in. the embodiments without departing from the spirit of the present invention. Such modifications are all within the scope of the present invention.

Numerical System for the Components

10, 20, 30, 40, 50A, 50B substrate.
10a, 10b, 22b, 23b, 32, 322, 323, 33, 43, 43t, 43b, 52, 53, 62 metal
100 coaxial LED
105 metal electrodes
11 LED chip
ha, lib electrode.
200 208 socket plate
22, 23 coaxial electrode lead.
22e, 23e, 32e, 33e, 43te, 43be, 53e metal extension
24 insulation material
25, 35, 45, 55 opening
322, 33 metal plate.
58 flange
62r recess.
66 protection glue.
72, 73 clip case.
722 sealing case
75 clip

1. A lighting board of diode with a coaxial lead, comprising:
(1) a coaxial light device, having a coaxial lead comprising an outer metal electrode around the coaxial lead and an inner metal electrode in the center of the coaxial lead, an insulation layer in between the outer metal and the inner metal; the inner metal electrode protruded outside of the outer metal electrode;
(2) a socket plate, having an opening for the coaxial light device to insert; a top metal for coupling to the outer metal electrode, and a bottom metal for coupling to the inner leads when the LED inserts;
(3) the coaxial light device exposing its top portion above the top metal for handling the coaxial light device; and
(4) a flip case, to house the elements of the socket plate without using any glue, solder, bolt, nut, or screw in between the elements of the socket plate.

2. The lighting board as claimed in claim 1, further comprising:
a metal, inside the opening, connected with the metal outside the opening.

3. The lighting board as claimed in claim 1, wherein, the section view of the opening is rectangle or step.

4. The lighting board as claimed in claim 1, further comprising:
a flange, located on the outer metal of the coaxial lead as a stop for the insertion of the coaxial light device.

5. The lighting board as claimed in claim 1, further comprising:
protection glue, covering the chip and top portion of the coaxial light device.

6. The lighting board as claimed in claim 1, said case is a permanent sealing case.

7. The lighting board as claimed in claim 1, further comprising:
a waterproof material, sealing around the junction between the coaxial light device and the case after the coaxial light device inserts.

8. The lighting board as claimed in claim 1, further comprising:
spiral around the outer metal of the coaxial lead, for screwing into the socket plate.
